(19) United States
(12) Patent Application Publication
(10) Pub. No.: US 2010/0211338 A1
(43) Pub. Date: Aug. 19, 2010

(54) METHOD AND DEVICE FOR ANALYZING ELECTRIC CABLE NETWORKS USING PSEUDO-RANDOM SEQUENCES

(76) Inventors: Nicolas Ravot, Chelles (FR); Yannick Bonhomme, Le Val Saint Germain (FR); Fabrice Auzanneau, Massy (FR)

Correspondence Address: LARIVIERE, GRUBMAN & PAYNE, LLP, 19 UPPER RAGSDALE DRIVE, SUITE 200, MONTEREY, CA, 93940, US

(21) Appl. No.: 12/446,742

(22) PCT Filed: Oct. 19, 2007
(86) PCT No.: PCT/EP2007/061230

§ 371 Date: Jun. 12, 2009

(30) Foreign Application Priority Data
Oct. 25, 2006 (FR) 06 09358

(51) Int. Cl. G01R 31/08; G06F 19/00

(52) U.S. Cl. 702/59; 702/58

(57) ABSTRACT

The invention relates to a method and a device for analyzing electric cable networks in order to detect and locate defects in the cables comprising at least one branch connection from which N secondary sections extend. The method involves injecting into the network, at a plurality of injection points E, pseudo-random sequences of digital signals PNi(t) that are de-correlated from each other, and collecting, at one or more observation points Sj, composite time signals Rj(t) generated by the circulation of the output sequences and the reflections thereof in the impedance discontinuities of the network. The correlation between the composite signals and the time-offset pseudo-random sequences is then computed, and the positions of correlation peaks are sought to deduce therefrom the positions of defects in the network by taking into account the signal propagation speed in the network.

The invention relates to a method and a device for analyzing electric cable networks, to detect, characterize and locate defects in the cable in such a network.

The electric cables concerned can be power transmission cables or communication cables, in fixed installations (distribution network, internal or external communication network) or mobile installations (power or communication network in an airplane, a boat, a motor vehicle, etc.). The cables can be of any type: coaxial or two-wire, in parallel lines or in twisted pairs, shielded or otherwise, and so on, provided that the signal propagation speed in these cables can be known. These networks can be organized in various known topologies: bus, tree, mesh, ring, star, linear or a hybrid of these various topologies.

The defects concerned are defects that can affect the electrical operation of the circuits of which the cables are part and that can have sometimes very critical consequences (electrical system failures in an airplane for example), or even defects that can directly cause fires to begin (short circuits, electrical arcs in dry medium or in the presence of moisture, etc.). It is important to be able to detect these defects to remedy them in time.

It will be understood that the problem of detecting the defects is all the greater when the electric cable networks are longer and more complex or when they are more difficult to access (buried cables, for example). This is why remote detection and locating systems have been devised, operating from one end of the cable. The methods used are “reflectometry” methods, in which a signal injected at one end of a cable is propagated in this cable and a portion of the amplitude of the signal is reflected at the position of the defect, because of the impedance discontinuity that the signal encounters at this position. If the signal propagation speed in the cable (linked to its characteristic impedance) is known, the measurement of the duration that separates the output wave from the reflected wave gives an indication of the distance between the end of the cable and the defect.

In the time-domain reflectometry (TDR) methods, an electromagnetic wave is injected into the cable in the form of a voltage pulse, a voltage level, or similar. The wave reflected at the position of the impedance discontinuity is detected at the injection position and the time difference between the output and received fronts is measured. The position of the defect is determined from this difference, and the amplitude and the polarity of the reflected pulse give an indication of the type of defect (open circuit, short circuit, resistive defect, or other).

There are also frequency-domain reflectometry (FDR) methods, which consist in injecting at the input of the cable a sinusoid frequency-wobulated continuously or by levels and in measuring the frequency or phase difference between the output wave and the reflected wave. The published patent application WO 02/068968 describes a frequency-domain reflectometry method. In a variant called SWR, for “Standing Wave Reflectometry”, the nodes and antinodes of a standing wave generated by the combination of an incident wave and its reflection are detected.

The frequency-domain reflectometry methods are effective for analyzing a simple cable. They are difficult to use when the cable includes branches. The time-domain reflectometry methods can be used even with branches, but analyzing the reflected signals is difficult because of the presence of multiple reflections.

Also proposed, in the published patent application WO 2004/005947, is a method that combines both time and frequency domains that consists in injecting a linearly wobulated signal with an envelope of Gaussian amplitude.

Spread-spectrum reflectometry methods have also been proposed, in the article entitled “Spread Spectrum Sensors for Critical Fault Location on Live Wire Networks” by Cynthia Furse et al., in the Journal of Structural Control and Health Monitoring, Volume 12, Issue 3-4, 2005. A signal is transmitted in the form of a low-level pseudo-random code over a network, even when it is in service; this signal and its echo reflected by any defect are correlated with variable time offsets to establish a time-dependent correlation curve. This curve shows correlation peaks with time offsets linked to the positions of the defects and the network junctions and/or branches. This system is particularly suited to the detection of intermittent defects because it can function even when the network is in use; now, the intermittent defects may very well only occur when the network is in service and disappear when it is no longer in service (for example, a defect that occurs when an airplane is flying but disappears on the ground). This method can be used for cables that include branches, but it retains ambiguities: it is impossible to say which branch contains a detected defect. U.S. Pat. No. 5,369,366 describes such a method.

The article by Eiji Nishiyama and Kenshi Kuwanami in the IEEE review 2002 0-7803-7525-4/02 pp 465 to 468 briefly describes a method that uses the injection of pseudo-random sequences at one or more points of a simple linear network in closed loop configuration.

A similar method, but one that quite simply uses the signals or natural noise circulating in the cable, and not a pseudo-random code injected at the input of the cable, has been proposed in the article by Chet Lo and Cynthia Furse entitled “Noise-Domain Reflectometry for Locating Wiring Faults”, published in IEEE Transactions on Electromagnetic Compatibility, Vol. 47 No. 1 Feb. 2005. Strong-correlation peaks are detected in a process of correlating the signal with itself. This method suffers from the same defect as the previous one, namely that it does not allow position ambiguities to be easily eliminated when there are several branches.

The aim of the invention is to help eliminate the defect position determination ambiguities of the prior methods, notably in cables having a T structure (also called Y structure), that is, comprising at least one branch.

To achieve this, the invention proposes a method of testing a cable network comprising at least one junction from which N secondary sections (N being greater than or equal to 2) extend, the method comprising the following operations:
injecting into the network, at a plurality of injection points Ei, pseudo-random sequences of digital signals PNi(t),
collecting, at one or more observation points Sj, composite time signals Rj(t) generated by the circulation of the output sequences and their reflections in the impedance discontinuities of the network,
computing a correlation function Kij(τ), at each of the observation points Sj and for each injection point Ei, this function representing, according to a variable delay τ, a time correlation value between on the one hand the composite signal Rj(t) present at this observation point and on the other hand pseudo-random sequences PNi(t−τ) identical to the sequences PNi(t) that are injected at the different points but delayed by the variable delay τ,
searching for characteristic values of τ for which the correlation curve Kij(τ) presents a peak,
determining the positions of cable defects according to the characteristic values found for each correlation Kij(τ),
the pseudo-random sequences injected at the different points being mutually non-correlated.

Thus, instead of injecting one and the same sequence at several points of the network, different and mutually non-correlated sequences are injected. The expression “non-correlated sequences” should be understood to mean sequences that are completely decorrelated, or little correlated, that is, their inter-correlation according to a delay T does not produce any significant correlation peak of amplitude comparable to the peak of self-correlation of a sequence with itself. In other words, the correlation of two little-correlated sequences mainly produces noise and not characteristic correlation peaks such as those that are generated by a sequence and the reflection of this same sequence on a network impedance discontinuity.

The sequences can be “pseudo-random sequences of type M”, or even “maximum length pseudo-random sequences”; these are sequences produced by a cascade of n shift registers with a loopback of the cascade on itself and intermediate loopbacks from the output of certain registers in the middle of the cascade (called linear feedback shift register or LFSR).

The weak correlation can be obtained notably by establishing pseudo-random digital sequences of different lengths (established by generators having different numbers of registers), or sequences that have sufficiently different bit rates, the ratio of which is not an integer and is preferably:
an irrational number,
or strictly a rational fraction of integer numbers.

The sequences can also be naturally de-correlated by choosing orthogonal pseudo-random sequences, such as codes used to separate GPS satellite channels or to separate telecommunication channels by spread spectrum (Gold codes, for example).

Pseudo-random sequences can be generated from characteristic polynomials of degree n (n being equal to the number of registers of the LFSR). To make best use of the capacities thereof and generate sequences of maximum length, the characteristic polynomial must be irreducible and in this case the period of the LFSR will be equal to T0=2ⁿ−1 (expressed in number of bits of the sequence). For a given sequence length and a given rate, a weak correlation can be obtained by choosing different characteristic polynomials. In practise, a minimum number n of registers is required for the polynomials to be de-correlated from each other. For example, if:
n=4, there are only two primitive characteristic polynomials, and they are not sufficiently de-correlated from each other;
n=6: there are 6 primitive characteristic polynomials;
from n=8, the characteristic polynomials are of sufficient length to be all de-correlated from each other.

One way of evaluating whether two sequences are sufficiently de-correlated from each other is to measure whether their inter-correlation ratio (level of the maximum inter-correlation peak between two different sequences/level of the maximum self-correlation peak of the same sequence) is typically less than 5 to 10%:

[MaxIntercorrelation−MinIntercorrelation]/[MaxSelfcorrelation]<=0.10

The device for implementing this method therefore comprises at least two sources of pseudo-random sequences of digital sequences that are mutually non-correlated and able to be connected at two points of a network to be tested, means of synchronizing the sources with each other, a device for detecting the composite signal present at least one point of the network, and means of computing the correlation function between this signal and each of the pseudo-random sequences delayed by a variable delay (τ).

Other features and benefits of the invention will become apparent from reading the detailed description that follows and which is given in reference to the appended drawings in which:

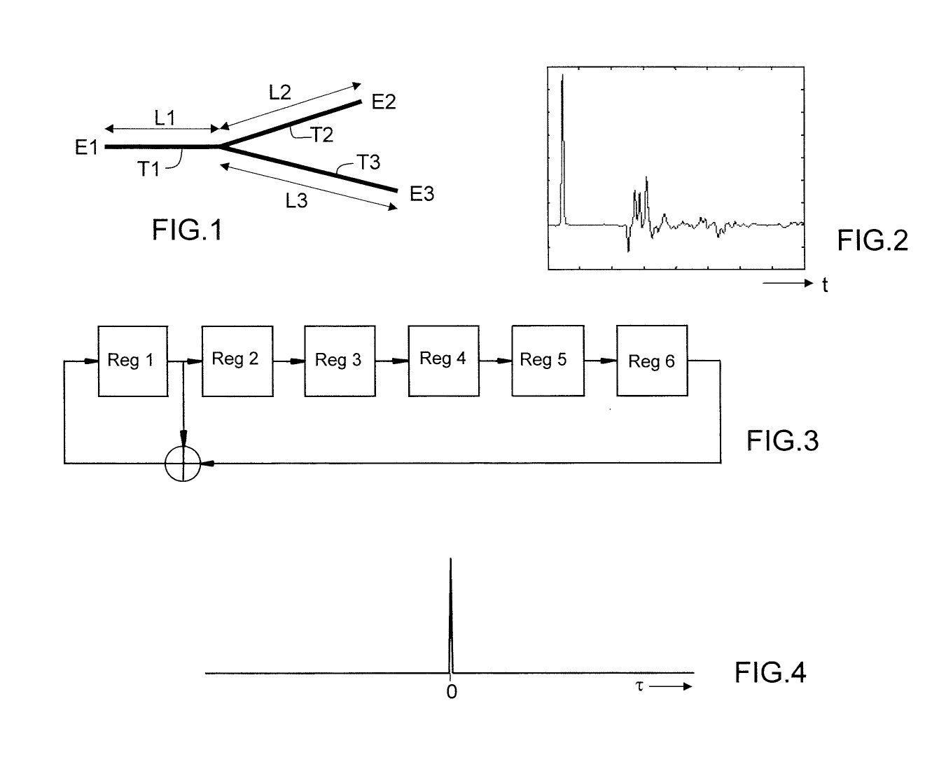

FIG. 1 represents, by way of example, a cable network with branching that is to be analyzed;

FIG. 2 represents a conventional time-domain reflectogram likely to appear in an analysis of the network by injection of a pulse;

FIG. 3 represents a type M pseudo-random sequence generator;

FIG. 4 represents the time-domain self-correlation function of a type M pseudo-random sequence;

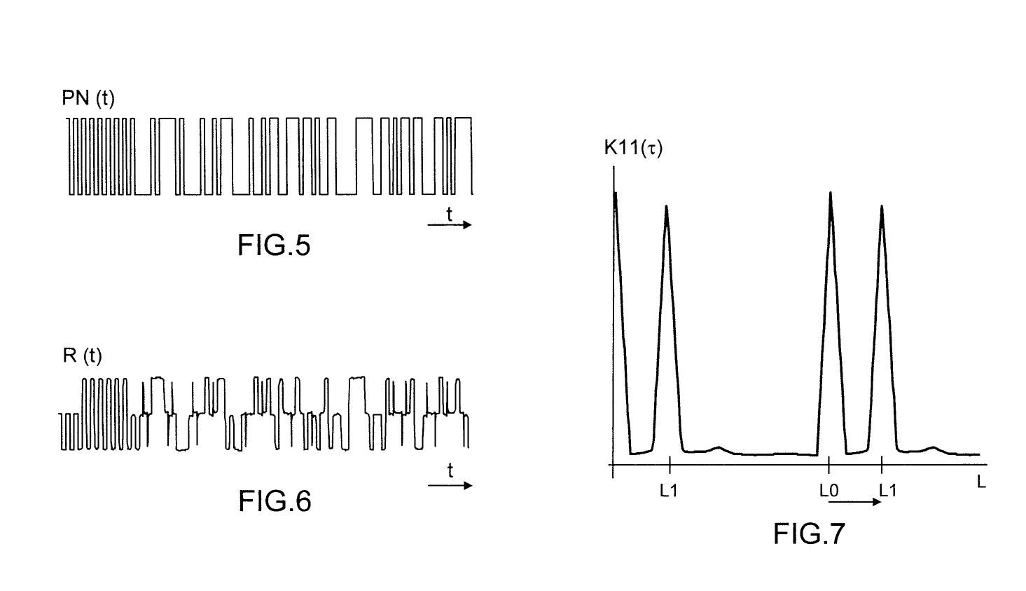

FIG. 5 represents a time-domain pseudo-random sequence PN(t);

FIG. 6 represents a composite signal R(t) obtained from the propagation of the pseudo-random sequence in a network;

FIG. 7 represents an exemplary time correlation curve K11(τ) between a signal such as that of FIG. 6 and a pseudo-random sequence that has generated it;

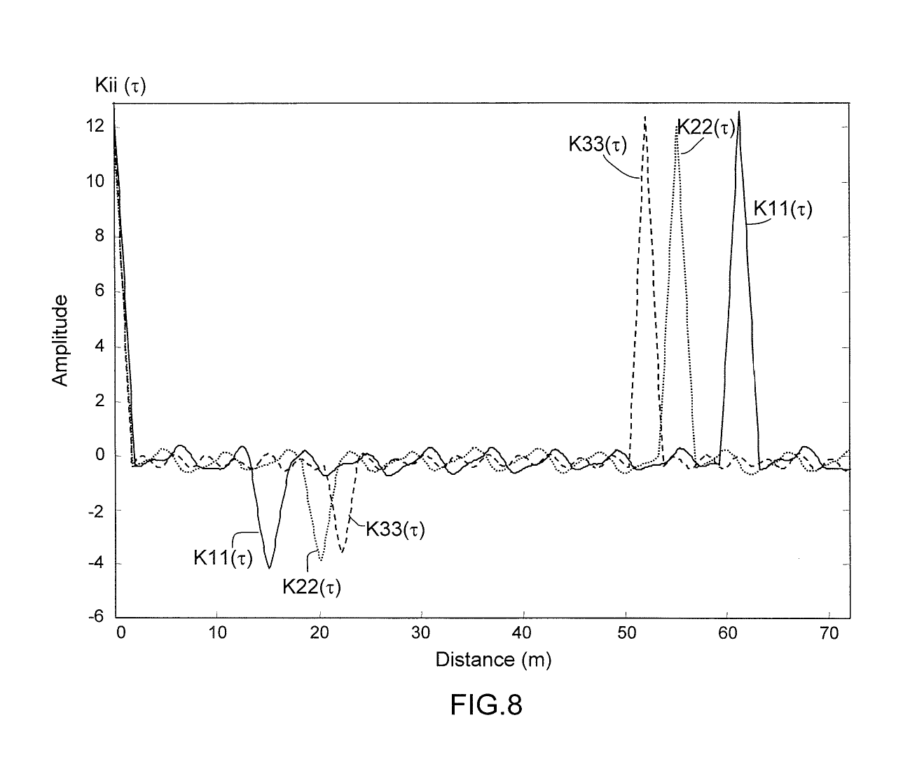

FIG. 8 represents the time correlation functions Kii(τ) between the composite signal present at each end of the network and the respective pseudo-random sequence injected at that same end;

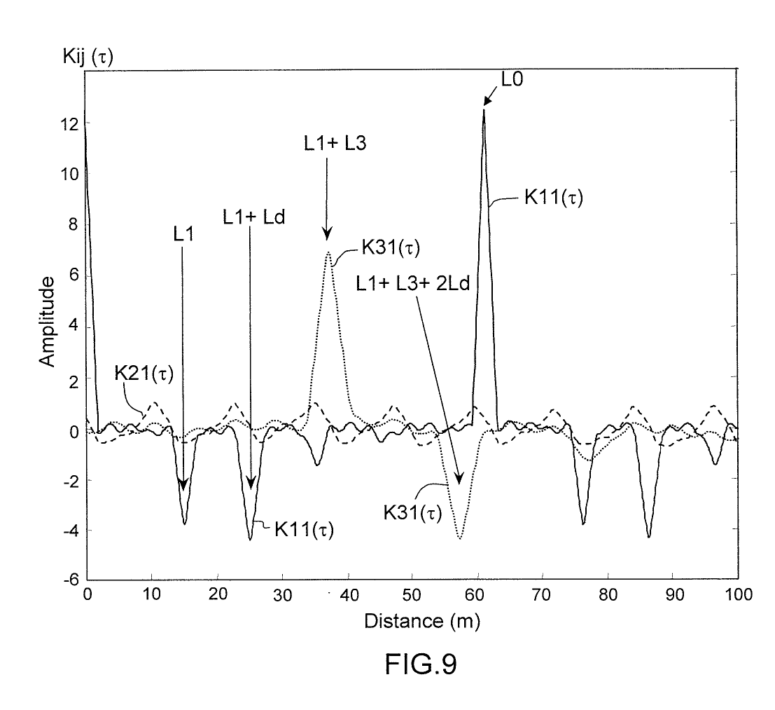

FIG. 9 represents the time correlation functions Kij(τ) between the composite signals Rij(t) collected at one end and the pseudo-random sequences injected at that end and at the other ends.

FIG. 1 diagrammatically represents a network with a junction and two branches, having three sections T1, T2 and T3. The sections T2 and T3 have an input end connected to a junction point A situated at an output end of the section T1. Thus, if the network is followed starting from an input end E1 of the latter, there are encountered, in turn, a length of cable L1 of the section T1, then a junction at A, and, depending on whether the section T2 or the section T3 is followed, respectively a length of cable L2 of the section T2 to its output end E2, or a length of cable L3 of the section T3 to its output end E3.

This is a simple example of a T (or Y) network. The sections concerned and represented by a line can consist of a sheathed conductive wire or a pair of sheathed wires or a coaxial cable. This network can be used immaterially to transport power or communication signals from the input E1 to the outputs E2 and E3, or in the opposite direction, from an output E2 or E3 to the other output or to the input E1. This is why the “ends” of the network are hereinafter called the inputs and outputs E1, E2, E3, bearing in mind that each of them can serve equally as an input or as an output, in normal use of the network or when searching for network defects; it should be noted that the search for detects can very well, in the present invention, be conducted in parallel with normal use.

The section ends E1, E2, E3 can be open-circuited or short-circuited, or loaded by a matched or unmatched impedance. If there is impedance matching, the test signals are not reflected at these ends. If there is a short circuit, there is no transmission beyond the short circuit and there is negative reflection. If there is an open circuit, there is reflection without or almost without attenuation. If there is an impedance mismatch, there is partial reflection.

In the conventional defect detection methods, a test pulse would typically be applied from the input E1, and a signal pattern called “time reflectogram” would be collected at this same input; the reflectogram is the plot of a curve representing the trend of a voltage amplitude recorded at the input E1 over time.

FIG. 2 represents such a reflectogram for the cable of FIG. 1, with time on the x axis and a voltage amplitude on the y axis. The input pulse, on the left in the diagram, is a positive pulse of short duration compared to the propagation durations in the cables in order for the reflected pulses not to be mixed with the output pulse. The reflected pulses are first of all a negative reflection pulse at the junction; the junction creates an impedance mismatch in which the impedance seen is lower than the characteristic impedance of the cable, hence the negative amplitude of the reflected signal. Then, there is a positive pulse reflected by the open-circuited end (high impedance) of the section T2, then a pulse that seems to derive from a round-trip path between the junction A and the end E2 of the second section. Then, a pulse occurs due to the reflection at the end E3 of the third section. Next, the pulses derived from other multiple or combined reflections appear, for example a pulse resulting from the reflection, at the end of the section T2, of a pulse already reflected by the end of the third section. The first pulses are the most significant, the others are more difficult to exploit.

If there is a defect in one of the sections, it can have the effect of displacing some of the pulses or quite simply adding pulses to the diagram of FIG. 2. It is therefore not easy to interpret the existence of a defect and find the location of the defect from such a reflectogram.

In the inventive method, a pulse is not injected at one point but pseudo-random sequences of binary signals are injected, at several points of the network (preferably the existing ends E1, E2, E3), the different sequences being de-correlated from each other.

A pseudo-random sequence consists of a series, of greater or lesser length, of bits of random distribution, this distribution being such that a correlation of this sequence with the same sequence delayed by a time τ gives a very narrow correlation peak around τ=0; outside of this narrow peak (width practically equal to the duration of two bits of the sequence), the correlation value is zero or in any case very low compared to the amplitude of the peak.

Such a sequence is generally produced by the cascading of several shift registers, a loopback of the cascade on itself, and exclusive-OR operations and/or intermediate loopbacks from the outputs of the registers.

Among the pseudo-random sequences, there are notably the sequences called M sequences or maximum length sequences which, from n cascaded registers, form sequences 2ⁿ−1 bits long. FIG. 3 represents an example with six cascaded registers forming an LFSR or linear feedback shift register. For example, with six registers, periodic sequences of 63 bits are produced, with a duration of the order of approximately a microsecond if the bit rate is approximately 50 Mbps (megabits per second). Such sequences can be used in the inventive method.

FIG. 4 represents the correlation of a sequence M with this same sequence delayed by a variable time τ (on the x axis). The correlation computation provides an almost zero signal except for a value of τ in a very narrow interval (width equal to the duration of two bits) where it presents a high peak; the center of the peak is situated at τ=0, for which the correlation is maximum. If the sequence is periodically re-output, a correlation peak clearly exists on each period. The output of periodic sequences is preferred if the sequences are fairly short, because this favors the correlation between the sequence and the signals that are circulating in the cable.

The time period of a sequence is defined as follows:

T0=[2ⁿ−1]/D

where n is the number of registers or the degree of the characteristic polynomial and D the rate of the sequence.

To obtain sequences that are de-correlated from each other, it is possible to choose sequences:
of different rate and of identical degree n;
of identical rate and of different degree n;
or, according to a preferred embodiment of the invention, identical sequences of degree n and of the same rate, by choosing different primitive characteristic polynomials for each LFSR.

FIG. 5 represents, by way of illustration, a pseudo-random bit sequence PN(t) output at 50 Mbps and lasting 1 microsecond.

Such a pseudo-random bit sequence can be output at one end of a network, such as, for example, the input E1 of the network of FIG. 1. It is propagated in the network, loses a little of its energy, may encounter impedance discontinuities (junctions, branch, short circuits, open circuits, unmatched loads, cable defects), may be partially reflected on these discontinuities, may be partly propagated beyond, encounter other discontinuities, etc., and reach the various ends of the network, including the starting end where it was injected.

The result of these propagation phenomena with losses and partial reflections is that a composite signal reappears at the input E1, and this composite signal, analog rather than digital, is the superimposition of the sequence initially injected and of several signals that each represent the same sequence but delayed and attenuated by the successive propagations and reflections.

The resultant of these sequences that are identical but of variable levels and different delays produces a composite signal such as, for example, that of FIG. 6. If this composite signal present at the input E1 is correlated with the initial sequence injected into this input, by delaying the latter by a variable duration τ, a correlation curve that is a function of the delay τ can be plotted. A maximum correlation peak will be found for a duration τ=0 if the instant at which the sequence is injected into the input is taken as the delay reference 0, since the injected sequence is present without offset at this instant, and a new maximum correlation peak will be found on each period T0 of injection of a new sequence if the sequence is injected periodically; the peak at τ=0 originates from the fact that the measured signal is the sum of the output signal and of the received signal but it is due to the measurement system; other correlation peaks will also be found each time a reflection or a series of reflections returns to the input E1 a signal that includes resemblances of its binary structure with the initial sequence.

Rather than graduating the x axis of the delay τ correlation curve, it is possible to graduate it by distance L along the network from the point of injection of the sequence, the correspondence being L=Vp·τ/2, where Vp is the propagation speed of the digital signals in the network and the factor 1/2 being there to take account of the fact that the path of the sequence includes a round trip between the injection point and the discontinuity point.

FIG. 7 represents an example of such a correlation curve K11(τ) in the case of a simple line section of length L1 open circuited at its ends. The x axis is the distance L=Vp·τ/2 between the injection end E1 and the other end, and the y axis is the correlation value K11(τ), between the sequence injected at the end E1 and the signal collected at E1. The first correlation peak corresponds to the injection instant, that is, a delay τ=0. The sequence is injected periodically with a period T0 (corresponding to a distance L0=Vp·T0/2) and another maximum correlation peak is therefore seen at L0. The other peaks represent the return of the sequence after reflection at the other end of the section after injection of a sequence; they are therefore situated at a distance L1 from each injection peak. The y-axis graduation is arbitrary.

The correlation function is obtained by computing, from the digitized time composite signal R1(t) present at E1 and from the pseudo-random sequence PN1(t), of which the structure, the length and the rate (50 Mbps for example) are known.

The correlation coefficient K11(τ), on the y-axis of FIG. 7, is the result of the correlation computation which is the integration, over a duration T starting from an instant −T/2 and extending to an instant +T/2, of the product of the pseudo-random sequence PN1(t−τ) injected at E1 and the composite signal R1(t) collected at E1:

$$K 11 ( τ ) = 1 / T {\int }_{- T / 2}^{+ T / 2} R 1 ( t ) . PN 1 ( t - τ ) . d t$$

T can correspond to one or more successive sequence periods.

It is this correlation function that can present the peaks that can be seen in FIG. 7, the x-axis variable being L=Vp·τ/2.

The computation is valid for any network and from any injection point, provided that the composite signal is observed at the injection point itself.

In the simple network of FIG. 1 that is assumed to be without defects, if the ends E2 and E3 are impedance matched, there will be a correlation peak at the time 0 and a peak reflecting the reflection on the junction A. If the ends E2 and E3 were not matched, other peaks would be found reflecting the impedance discontinuities; typically, if the ends E2 and E3 were open-circuited, there would be at least one correlation peak for each of the values

τₐ=2L1/Vp because of the junction A

τ_{b}=2(L1+L2)/Vp due to the end E2

τ_{c}=2(L1+L3)/Vp due to the end E3

If there were a defect at a distance Ld from the input E1, there would be at least one correlation peak for a delay corresponding to the propagation over a distance 2Ld, that is, at τ_{d}=2Ld/Vp. The existence of such a peak does not make it possible to easily know where the defect is, because Ld is greater than L1 (defect beyond the junction A).

However, this signal injected at E1 generates at E2 and E3 other composite signals having a resemblance with the injected digital signal PN1(t), and these signals R2(t), R3(t) can be correlated with the injected sequence to give correlation peaks that also provide information on the structure of the network or that confirm the indications given by the first correlation function K11(τ).

Thus, if R2(t) and PN1(t) are correlated, it should be possible to see a correlation peak at an instant τ_{L1+L2}=(L1+L2)/Vp since this delay τ_{L1+L2} is the time taken by the sequence to come directly from the end E1 to the end E2 (the delay τ=0 being taken with the same reference as for the first correlation). Similarly, a correlation peak should be seen between the composite signal R3(t) at E3 and the sequence PN1(t) output at E1, this peak being centered on an instant τ_{L1+L3}=(L1+L3)/Vp.

However, in the same way, it is also possible to inject at the ends E2 and E3 two other pseudo-random sequences PN2(t) and PN3(t), and the composite signal R1(t) then present at the point E1 can be correlated with each of these pseudo-random sequences, to culminate in respective correlation functions K21(τ) which is the correlation of the composite signal R1(t) present at E1 with the sequence PN2(t) output at E2, and K31(τ) which is the correlation of the composite signal R1(t) present at E1 with the sequence PN3(t) output at E3. If the delay reference τ=0 is taken at the same reference instant (instant of injection of the sequence PN1(t)), then the correlation functions K21(τ) and K31(τ) should respectively show a correlation peak at an instant τ_{L1+L2}=(L1+L2)/Vp and a peak at an instant τ_{L1+L3}=(L1+L3)/Vp, the network being assumed to be without defects between E1, E2 and E3.

According to the invention, these other pseudo-random sequences are not correlated with each other or correlated with the first, in order for the computed correlation functions to be able to fully distinguish where the sequences giving rise to correlation peaks originate from.

More generally, N injection points Ei will therefore be taken, these points normally being the accessible ends of the network (but could be other points), and injecting therein N pseudo-random sequences of binary signals that are not correlated with each other, PNi(t), i varying from 1 to N; correlation computations will be performed between each sequence PNi(t) and each of the composite signals Rj(t) that appear at K observation points Sj, j varying from 1 to K. The observation points are preferably the injection points. From these computations, more accurate (that is less ambiguous) information than the information given by the correlation peaks of just the sequence PN1(t) is then deduced.

At an observation point Sj, the following correlation computations are carried out, for some or all of the indices i and j associated with the injection points and with the observation points:

$$Kij ( τ ) = 1 / T {\int }_{- T / 2}^{+ T / 2} Rj ( t ) . PNi ( t - τ ) . d t ,$$

including, obviously, the computation for i=j, namely:

$$Kii ( τ ) = 1 / T {\int }_{- T / 2}^{+ T / 2} Ri ( t ) . PNi ( t - τ ) . d t$$

These computations make it possible to plot correlation curves as a function of τ and find correlation peaks.

If the injected pseudo-random sequences were the same, the result would be, in the case of the network of FIG. 1 assumed to be without defects, correlation curves that are difficult to interpret; in practise, at an observation point, propagation sequences arrive that can originate from any injection point since all intrinsically contain a resultant form of one and the same initial sequence. There are therefore many ambiguous correlation peaks.

However, if the pseudo-random sequences present a zero or very low mutual intercorrelation, the different correlations with the composite signals can be distinguished from each other. The different correlation functions computed at one and the same observation point Sj will separately show peaks resulting from the different sequence injection points. It is relative to this injection point that the positions of the impedance discontinuities will be measured.

The diagram of FIG. 8, once again plotted in the case of the network of FIG. 1, without defects and having ends that are impedance matched, shows the superimposition of the correlation curves Kii(τ), returned to one and the same origin τ=0. The solid line curve corresponds to a sequence injected at E1 and observed at E1; the dotted line curve corresponds to a sequence injected at E2 at the same moment and observed at E2; and the dashed line curve corresponds to a sequence injected at E3 and observed at E3. The section L1 is 15 meters, the sections L2 and L3 are 20 m and 22 m respectively. The graduation of the x-axes is by distance between the observation point and a defect (that is, the x-axis graduation does not represent the real propagation duration τ corresponding to the peak, but half of that duration).

The peaks corresponding to the reflection at the junction A in this case have a negative sign. There will be a peak for the correlation with the sequence PN1(t) observed at E1, at a distance of 15 meters corresponding to the length L1 of the section T1, a peak for the correlation with the sequence PN2(t) observed at E2, at a distance of 20 m corresponding to the length L2 of the section T2, and a peak for the correlation with the sequence PN3(t) observed at E3, at a distance of 22 m corresponding to the length L3 of the section T3.

The peaks of positive sign are the self-correlation peaks at the input and originate from the periodicity of the injection of the pseudo-random sequence. The sequences PN1(t), PN2(t) and PN3(t) are of different durations and therefore of different periodicities. The de-correlation is in this case produced in such a way that the bit sequences PN1(t) to PN3(t) are of different duration, which explains the three different positions of the self-correlation peaks; these different durations are obtained either by sequences of identical structure but different bit rate, or by sequences of different lengths in terms of number of bits, therefore of different structures, and of identical or different bit rate.

In the example of FIG. 8, the sequences are of different rates, respectively PN1(t): 50 Mbps, PN2(t): 55 Mbps, and PN3(t): 60 Mbps.

The de-correlation of the sequences could also be obtained by choosing sequences of identical duration and identical period, but with different characteristic polynomials for each LFSR. In this case, the self-correlation peaks K11(τ), K22(τ) and K33(τ) would be superimposed on each signal injection period.

FIG. 9 represents all the correlation functions corresponding to a single observation point which is the end E1, in the presence of the simultaneous injection of different sequences PN1(t), PN2(t) and PN3(t) respectively at the three ends E1, E2, E3. These functions are represented in the case of the presence of a defect in the section L2.

For the direct legibility of FIG. 9, it will be noted that different x-axis graduations have been used depending on whether the correlation function represented is a correlation with a reflected signal (correlation of type Kii(τ)) or a correlation with a signal transmitted directly without round trip (correlation of type Kij(τ) with i different from j). For a correlation with a simple outbound path, the distance graduation corresponds to the propagation duration (L=Vp·τ); for a correlation with a round-trip signal, the distance graduation corresponds to half the propagation duration (L=Vp·τ/2). It is a simple device for presenting the diagram, making it possible to place all the correlation peaks at places which correspond to physical distances (on the cable) measured simply in the outbound direction, rather than placing certain peaks at positions corresponding to a round-trip duration whereas others would be placed at positions corresponding to a simple outbound duration.

In FIG. 9, the solid-line curve, graduated in distances corresponding to τ/2, corresponds to the correlation function K11(τ) between the sequence PN1(t) injected at E1 and the composite signal R1(t) observed at E1. There is a starting self-correlation peak at t=0, and another at L0 corresponding to the injection period T0 of the sequences. The length L0 in the graph corresponds to VpT0/2. There is a negative intermediate peak at the length L1 (15 m) as in FIG. 8, corresponding to the position of the junction A. However, there is also a peak at approximately 25 m. It can be deduced therefrom that there is a defect beyond the junction A, on the section T2 or the section T3, at a distance Ld (approximately 10 m) from the junction A, a defect that generates a reflection to the input E1.

The dotted-line curve, graduated in distances corresponding to τ, corresponds to the correlation function K21(τ) between the sequence PN2(t) injected at E2 and the composite signal R1(t) observed at E1. This curve presents almost no correlation peak; this means that the signal injected at E2 does not or almost does not reach the input E1; it can be concluded therefrom that the defect whose existence has been confirmed by the curve K11(τ) is a short circuit that interrupts the propagation toward the end E2.

The defect is therefore probably a short circuit on the section T2 at the distance Ld of approximately 10 meters from the junction A.

The third, dashed-line curve, also graduated in distances corresponding to τ, corresponds to the correlation function K31(τ) between the sequence PN3(t) injected at E3 and the composite signal R1(t) observed at E1. This curve presents a positive peak at the distance L3+L1 (37 meters) showing a direct path (without defect) of the sequence from the end E3 to the end E1. It also presents a negative peak at a distance of approximately 57 meters. This peak apparently results from the following propagation from the end E3 to the end E1: propagation in the section T3 (L3: 22 m), partial reflection at A toward the section T2, propagation over T2 to the defect (Ld: 10 m), return from the defect to the junction (Ld: 10 m), and propagation over the section T1 (L1: 15 m). In total: L3+2Ld+L1=57 meters.

The correlation function K31(τ) therefore unambiguously confirms the presence of the defect on the section T2, its short-circuit nature, and its position.

It would also be possible to compute and plot the unrepresented correlation functions K22(τ), K33(τ) as in FIG. 8. The curve K22(τ) would show a peak at a distance L2-Ld, because of the defect, instead of the peak at the distance L2; the curve K33(τ) would also show the peak at the distance L3, but there would also be a peak at L3+Ld. These curves can be used to confirm the preceding observations made in FIG. 9.

It would also be possible to plot the correlation functions K23(τ) and K32(τ). In the example of the defect indicated hereinabove, there would be nothing to see on these curves because of the short-circuit defect on the section T2, which prevents any propagation from E2 to E3 or vice versa.

Finally, it would of course be possible to plot the curves K12(τ) and K13(τ), but it will be understood that they are redundant with the curves K21(τ) and K31(τ).

To implement the invention, it is essential to generate pseudo-random sequences that are decorrelated from each other; there are several ways of obtaining this decorrelation, as has been indicated hereinabove.

First of all, if the bit sequences are longer, it is easier to decorrelate them from each other than if they are shorter. Sequences of 64 bits or more are preferable.

Then, some pseudo-random sequence generators are designed to allow for the production of mutually orthogonal sequences, that is, sequences that present a zero or very low inter-correlation in principle regardless of the time offset between the sequences. The Gold pseudo-random codes are an example thereof. Such codes are well known in satellite positioning techniques where they are used to separate the channels from each other.

Also, the type M pseudo-random sequences (“maximum length” sequences) generated by a cascade of n registers are very little correlated with each other if they have different lengths (in number of bits), that is, if the number of registers of the cascade is different from one sequence to another.

Also, the type M pseudo-random sequences are very little correlated with each other and are therefore ideal if they have different bit rates, even if they have the same length in number of bits. The rates must not be multiples of one another and, if possible, their ratio must not be too simple when this ratio is a rational number: a ratio of rates equal to a simplified rational fraction is ideal if the numerator and the denominator are sufficiently high; in other words, a ratio of numbers that are too small, like 2/3 or 3/4, is to be avoided; a ratio of 7/8 or a ratio of higher numbers is preferred. A ratio equal to an irrational number is desirable provided, obviously, that it is not very close to the numbers to be excluded hereinabove (integer number, rational fraction of numerator and denominator that are too small). An irrational number that differs by at least 5% with one of the numbers to be excluded is ideal for a sequence of at least 64 bits. For example, rates of 50, 55 and 60 Mbps have been chosen for the analysis of the network in FIG. 9.

The implementation of the invention also comprises means of acquiring composite signals, of digitizing these signals and of computing the correlation functions. According to a preferred embodiment of the invention, the sources used to generate the different pseudo-random sequences are of fixed and identical rate, for reasons of synchronization and distribution of the clocks. The decorrelation is obtained by using distinct characteristic polynomials.

The number of registers n is adapted according to the problem to be dealt with, and in particular the length of the network, as well as the desired test period.

The invention makes it possible to detect, characterize and locate the defects of a wired network, even if it has a complex topology. It also makes it possible to identify the exact topology in the absence of a defect (precise section length measurements, etc.). The analysis of the network can be done while the network is being used normally, in particular for power transport networks, but also for communication networks, provided, however, that the bit rates of the pseudo-random sequences are sufficiently different from the network's normal communication rates.

In the case of a network with more complex topology than that of FIG. 1, the diagnostic means consists of a certain number of systems conforming to the invention such as those described hereinabove, distributed at carefully chosen places in the network in order for them to be able to monitor the simpler topology subnetworks, similar for example to that of FIG. 1.

1. A method of testing a cable network comprising at least one junction from which N secondary sections (N being greater than or equal to 2) extend, the method comprising the following operations:
injecting into the network, at a plurality of injection points Ei, pseudo-random sequences of digital signals PNi(t),
collecting, at one or more observation points Sj, composite time signals Rj(t) generated by the circulation of the output sequences and their reflections in the impedance discontinuities of the network,
computing a correlation function Kij(τ), at each of the observation points Sj and for each injection point Ei, this function representing, according to a variable delay τ, a time correlation value between on the one hand the composite signal Rj(t) present at this observation point and on the other hand pseudo-random sequences PNi(t−τ) identical to the sequences PNi(t) that are injected at the different points but delayed by the variable delay r,
searching for characteristic values of τ for which the correlation curve Kij(τ) presents a peak,
determining the positions of cable defects according to the characteristic values found for each correlation Kij(τ),
the pseudo-random sequences injected at the different points being mutually non-correlated.

2. The method as claimed in claim 1, wherein the sequences are so-called “maximum length” sequences or sequences M produced by a cascade of n shift registers with loopbacks.

3. The method as claimed in claim 1 wherein the pseudo-random sequences have different bit rates.

4. The method as claimed in claim 3, wherein a ratio of the bit rates between two pseudo-random sequences is an irrational number, or a rational fraction of integer numbers.

5. The method as claimed in claim 2, wherein the pseudo-random sequences have different lengths, expressed in number of bits.

6. The method as claimed in claim 1 wherein the pseudo-random sequences are mutually orthogonal sequences, inherently presenting a mutual inter-correlation that is almost zero regardless of their time offset.

7. The method as claimed in claim 6, wherein each pseudo-random sequence corresponds to an nth degree primitive characteristic polynomial.

8. The method as claimed in claim 6, wherein the inter-correlation ratio between two sequences is less than 10%:
(MaxIntercorrelation−MinIntercorrelation)/(MaxSelf-correlation)<=0.10

9. A device for testing a cable network comprising at least one junction from which N secondary sections (N being greater than or equal to 2) extend, comprising at least two sources of pseudo-random sequences of digital signals that are mutually non-correlated and able to be connected at two points of a network to be tested, means of synchronizing the sources with each other, a device for detecting the composite signal present at least one point of the network, and means of computing the correlation function between this signal and each of the pseudo-random sequences delayed by a variable delay (τ).

10. The method as claimed in claim 2 wherein the pseudo-random sequences have different bit rates.

11. The method as claimed in claim 2 wherein the pseudo-random sequences are mutually orthogonal sequences, inherently presenting a mutual inter-correlation that is almost zero regardless of their time offset.

12. The method according to claim 3, wherein the pseudo-random sequences have different lengths, expressed in number of bits.
